(19) United States
(12) Patent Application Publication
(10) Pub. No.: US 2010/0009543 A1
(43) Pub. Date: Jan. 14, 2010

(54) Method For Manufacturing Semiconductor Device

(76) Inventor: Eun-Sang Cho, Yongin-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/391,017

(22) Filed: Feb. 23, 2009

(30) Foreign Application Priority Data
Jul. 10, 2008 (KR) 10-2008-0067147

(51) Int. Cl. H01L 21/467

(52) U.S. Cl. 438/735; 257/E21.486

(57) ABSTRACT

Disclosed is a method for manufacturing a semiconductor device. The method includes sequentially depositing a polishing stop film and a mask oxide film on a semiconductor substrate, forming a photosensitive film pattern on the mask oxide film to expose a device isolation region, sequentially etching the mask oxide film and the polishing stop film under first and second etching process conditions using the photosensitive film pattern as a mask to form a hard mask pattern, and etching the semiconductor substrate under third etching process conditions using the hard mask pattern to form a trench for a device-isolation film. Advantageously, the method simplifies an overall process without using a spacer and secures a desired margin in the subsequent processes, e.g., gap-filling an insulating material in the trench and chemical mechanical polishing of the insulating material.

This application claims the benefit of Korean Patent Application No. 2008-0067147, filed on 10 Jul. 2008, which is hereby incorporated by reference as if fully set forth herein.

### BACKGROUND OF THE INVENTION

1. Field of the Invention

The present invention relates to a semiconductor device. More specifically, the present invention relates to a method for manufacturing a semiconductor device that includes forming a device isolation region using a hard mask.

2. Discussion of the Related Art

In general semiconductor processing, a device-isolation film is formed to divide a semiconductor substrate into a device-isolation region and an active region. Photolithographic and spacer processes may be used for formation of the device-isolation film. Processes that form features having critical dimensions not less than 250 nm utilize photolithography to form the device-isolation film. Meanwhile, as a semiconductor device becomes smaller, a trench for forming a device-isolation film becomes narrower and deeper. Thus, processes for forming device-isolation films in smaller semiconductor devices may utilize spacer processes using one or more spacers. The spacer process secures additional margin for formation of pattern critical dimensions (CD), which may be difficult to define by a photo process alone.

Hereinafter, a general method for manufacturing a semiconductor device using a spacer process to form a trench for a device-isolation film will be described with reference to the annexed drawings.

FIGS. 1A to 1D are sectional views illustrating a general method for manufacturing a semiconductor device using a spacer process.

As shown in FIG. 1A, a silicon nitride film 12 and a silicon oxide film 14 are sequentially deposited on a semiconductor substrate 10. Then, a photosensitive film pattern 16 to expose a device isolation region is formed on the silicon oxide film 14, and as shown in FIG. 1B, the silicon nitride film 12 and the silicon oxide film 14 are etched using the photosensitive film pattern 16 as an etching mask to form a hard mask including a silicon nitride film pattern 12A and a silicon oxide film pattern 14A.

Subsequently, as shown in FIG. 1C, the photosensitive film pattern 16 is removed by ashing, then a material such as silicon oxide may be conformally deposited onto the hard mask to form a spacer 18 over the entire surface of the semiconductor substrate 10, including the silicon nitride film pattern 12A and the silicon oxide film pattern 14A.

Subsequently, as shown in FIG. 1D, the semiconductor substrate 10 is etched using the hard mask including the spacer 18, the silicon nitride film pattern 12A and the silicon oxide film pattern 14A as an etching mask to form a trench 20 for a device-isolation film.

FIGS. 2A and 2B are scanning electron microscope (SEM) images of sectional views illustrating a method for manufacturing a semiconductor device using a spacer process.

FIG. 2A shows a state wherein a dense line is patterned using an ArF photoresist. FIG. 2B shows the pattern of the dense line after formation of the hard mask. Referring to FIG. 2B, profiles are flat without any bent portions. However, the spacer process may require more steps, as compared to a photolithography process alone.

### SUMMARY OF THE INVENTION

Accordingly, the present invention is directed to a method for manufacturing a semiconductor device that substantially obviates one or more problems due to limitations and disadvantages of the related art.

It is an object of the present invention to provide a method for manufacturing a semiconductor device that forms a trench for a device-isolation film without using any spacer.

To achieve these objects and other advantages and in accordance with the purpose of the invention, as embodied and broadly described herein, provided is a method for manufacturing a semiconductor device, including: sequentially depositing a polishing stop film and a mask oxide film on a semiconductor substrate; forming a photosensitive film pattern on the mask oxide film to expose a device isolation region; sequentially etching the mask oxide film and the polishing stop film under first and second etching conditions (respectively) using the photosensitive film pattern as a mask to form a hard mask pattern; and etching the semiconductor substrate under third etching conditions using the hard mask pattern to form a trench for device-isolation film.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and along with the description serve to explain the principle(s) of the invention. In the drawings:

FIGS. 1A to 1D are sectional views illustrating a general method for manufacturing a semiconductor device using a spacer process;

FIGS. 2A and 2B are SEM images of sectional views illustrating a method for manufacturing a semiconductor device using a spacer process;

FIGS. 3A and 3F are sectional views illustrating a method for manufacturing a semiconductor device according to embodiments of the present invention;

FIG. 4 is a graph showing a correlation between a thickness of the polishing stop film (e.g., a silicon nitride film) and a thickness of the mask oxide film (e.g., a TEOS layer); and

FIGS. 5A to 5E are SEM images of a semiconductor device manufactured by an exemplary method according to the present invention.

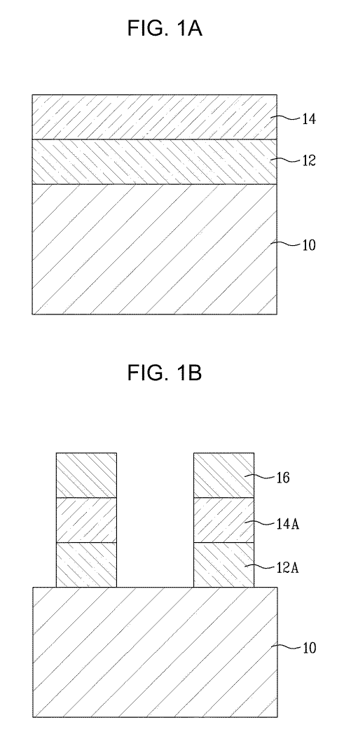

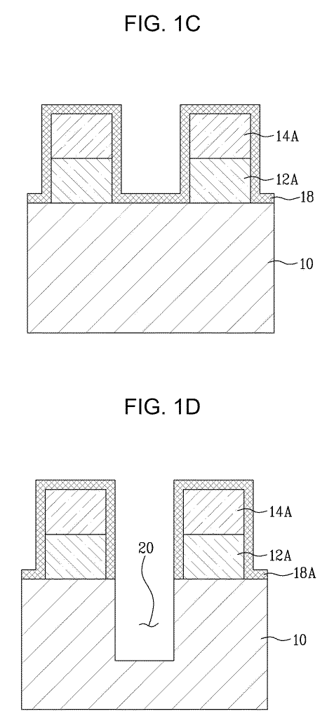

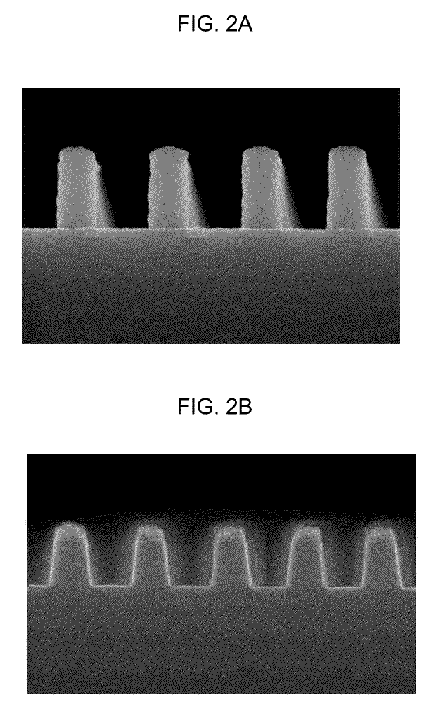

### DETAILED DESCRIPTION OF THE INVENTION

Hereinafter, preferred embodiments of the method for manufacturing a semiconductor device according to the present invention will be described in detail with reference to the accompanying drawings.

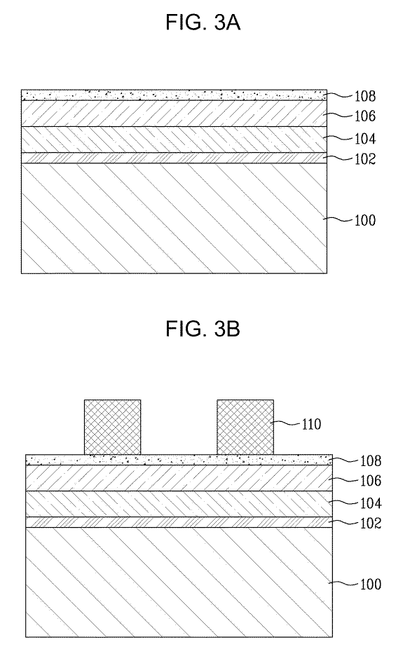

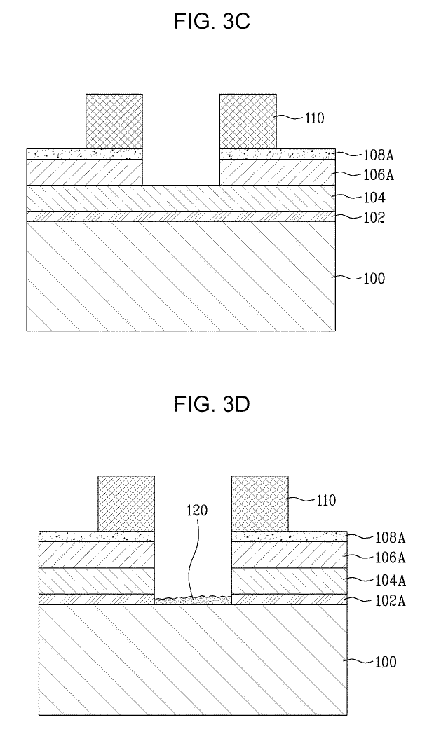

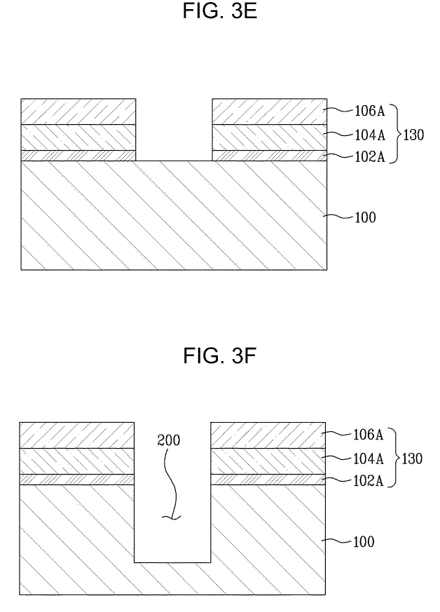

FIGS. 3A and 3F are sectional-views illustrating a method for manufacturing a semiconductor device according to various embodiments.

Referring to FIG. 3A, a pad oxide film 102, a polishing stop film 104, a mask oxide film 106 and an anti-reflective coating 108 are sequentially deposited on a semiconductor substrate 100.

That is, the pad oxide film 102 is formed on the semiconductor substrate 100. The pad oxide film 102 generally comprises silicon dioxide, and may be formed by thermal oxidation or blanket deposition (e.g., chemical vapor deposition [CVD], which may be plasma-assisted or plasma-enhanced, from a precursor gas such as silane or TEOS). The polishing stop film 104 is formed on the pad oxide film 102. The polishing stop film 104 may be or comprise a silicon nitride (SiN) film. The mask oxide film 106 is formed on the polishing stop film 104. The mask oxide film 106 may be or comprise tetraethoxysilane (TEOS) or a silicon oxide (SiO₂) film formed by deposition (e.g., CVD). The anti-reflective film 108 is formed on the mask oxide film 106 and may comprise any known material that reduces reflection of light from interfaces between different materials below the anti-reflective film 108, such as silicon oxynitride or an organic anti-reflective material. The anti-reflective film 108 may have a thickness of 250˜350 Å.

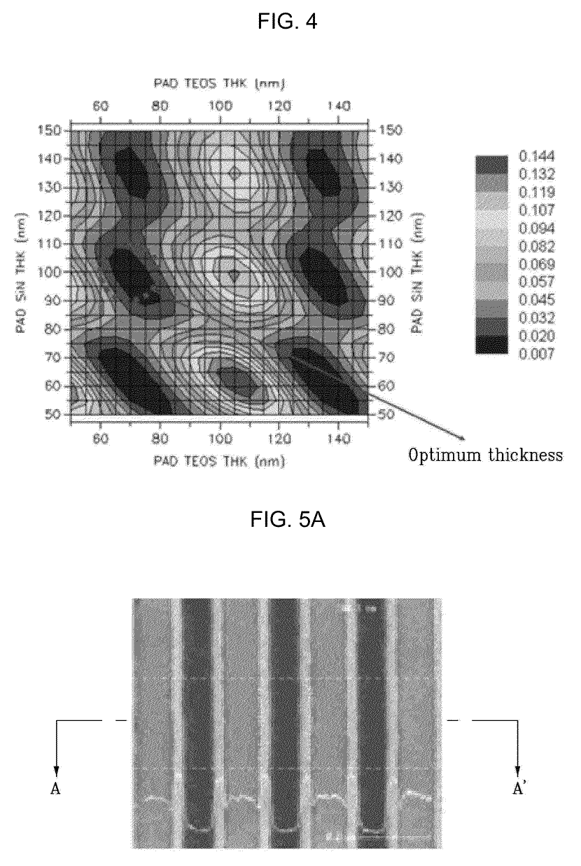

FIG. 4 is a graph showing a correlation between a thickness of the polishing stop film 104 (e.g., silicon nitride film) and a thickness of the mask oxide film 106 (e.g., TEOS), wherein a horizontal axis represents a TEOS thickness and a vertical axis represents a silicon nitride film thickness.

From FIG. 4, optimum thicknesses of the polishing stop film 104 (e.g., silicon nitride film) and the mask oxide film 106 (e.g., TEOS) can be seen. For example, optimum thicknesses of TEOS and Si₃N₄ are 500˜900 Å and 800˜1,200 Å, respectively, and a preferred thickness for the anti-reflective film 108 is 750˜890 Å.

Subsequently, as shown in FIG. 3B, a photosensitive film pattern 110 is formed on the anti-reflective film 108 such that it exposes a device isolation region. The photosensitive film pattern 110 may be obtained by applying a photoresist to the surface of the anti-reflective film 108 and patterning the photoresist by photolithography. A preferred thickness of the photosensitive film pattern 110 is 3,200˜3,600 Å.

Subsequently, as shown in FIGS. 3C to 3E, the mask oxide film 106 and the polishing stop film 104 are sequentially dry-etched under first and second etching process conditions using the photosensitive film pattern 110 as an etching mask to form a hard mask pattern 130. At this time, the anti-reflective film 108 and the pad oxide film 102 (or, alternatively, the mask oxide film 106) may be etched. A more detailed explanation of this step will be given below.

As shown in FIG. 3C, the anti-reflective film 108 and the mask oxide film 106 are dry-etched under first etching process conditions using the photosensitive film pattern 110 as a mask. An etch selectivity ratio between the photosensitive film pattern 110 and the mask oxide film 106 can be adjusted to a desired level by controlling at least one of the amount or flow of a reaction gas and RF power used for etching the mask oxide film 106 under the first etching process conditions. That is, the etch selectivity ratio between the photosensitive film pattern 110 and the mask oxide film 106 can be controlled or determined by first etching process conditions including at least one of the amount or flow a reaction gas and by the RF power. An increase in etch selectivity ratio between the photosensitive film pattern 110 and the mask oxide film 106 minimizes consumption of the photoresist. A decrease in consumption of the photoresist involves the use of a relatively small amount or flow of reaction gas and a low RF power. Accordingly, by reducing consumption of the photoresist, the partial pressure ratio of the reaction gases and the RF power can be decreased in order to improve the etch selectivity ratio between the photosensitive film pattern 110 and the mask oxide film 106.

For first process conditions, the reaction gases may include an oxygen source (e.g., O₂, O₃, N₂O, NO, NO₂, etc.), and a fluorocarbon gas (e.g., a compound of the formula CₓF_{z}, where x is from 1 to 5 and z is 2x−2, 2x or 2x+2) and/or a hydrofluorocarbon gas (e.g., a compound of the formula CₓH_{y}F_{z}, where x is from 1 to 4, y is from 1 to x, and y+z is 2x or 2x+2). In one embodiment, only CF₄ and CHF₃ are used as reaction gases. Alternatively, O₂ and Ar may be further used as a reaction gas and an inert gas, respectively. O₂ serves to remove polymers and Ar serves to stabilize the pressure of the etching chamber. As a result, in one embodiment, it is preferred to use a flow rate of the oxygen source that is lower than combined flow rate of the fluorocarbon and/or hydrofluorocarbon gases, preferably lower than each of the fluorocarbon and hydrofluorocarbon gases.

The first etching process conditions according to preferred embodiments of the present invention include O₂ at a flow rate of 5 to 10 sccm; Ar at a flow rate of 100 to 200 sccm; CF₄ at a flow rate of 30 to 50 sccm; and CHF₃ at a flow rate of 15 to 25 sccm.

The mask oxide film 106 is etched to form a mask oxide film pattern 106A, and the polishing stop film 104 is dry-etched under second etching process conditions, as shown in FIG. 3D. For the second etching process conditions, the reaction gases may include an oxygen source and a fluorocarbon gas, as described above. The second etching process conditions according to embodiments of the present invention include: O₂: 3 to 7 sccm; Ar: 100 to 200 sccm; and CF₄: 70 to 90 sccm.

When etching the polishing stop film 104, a partial pressure ratio between O₂, Ar and CF₄ may be 1:27˜36:14˜18. Thus, the flow rate of the oxygen source can be from about 5% to about 8% of the flow rate of the fluorocarbon gas under the second etching process conditions.

In brief, exemplary first and second etching process conditions are summarized in Table 1 below:

TABLE 1

| | First etching | Second etching |
|---|---|---|
| Items | process conditions | process conditions |
| O₂ (sccm) | 5~10 | 3~7 |
| Ar (sccm) | 100~200 | 100~200 |
| CF₄ (sccm) | 30~50 | 70~90 |
| CHF₃ (sccm) | 15~25 | 0 |

Meanwhile, by controlling a vacuum level (e.g., pressure) of a chamber in which the mask oxide film 106 and the polishing stop film 104 are etched, a straightness degree for etching of the mask oxide film 106 and the polishing stop film 104 can be controlled. The improvement of the degree of etching straightness can be obtained by rapidly removing by-products caused by etching, or increasing the power applied to the plasma during etching. An increased power causes an increase in the photoresist consumption amount and thus deteriorates an etch selectivity ratio between the photosensitive film pattern 110 and the mask oxide film 106 (or, alternatively, the polishing stop [e.g., silicon nitride] layer 104). Accordingly, in order to rapidly remove by-products, a chamber vacuum level is reduced relative to the pressure during the first etching process conditions.

After the polishing stop film 104 and the mask oxide film 106 are etched to form the polishing stop film pattern 104A and the mask oxide film pattern 106A, the photosensitive film pattern 110 and the anti-reflective film pattern 108A are removed. The photosensitive film pattern 110 is generally removed by ashing (e.g., exposure to a plasma containing an oxygen source [e.g., O₂ and/or O₃], with optional heating), as is the anti-reflective film pattern 108A when it is an organic anti-reflective material. The anti-reflective film pattern 108A may be removed by selective wet or dry etching when it comprises a silicon oxynitride.

When the polishing stop film 104 is etched to expose the semiconductor substrate 100, the surface of the exposed semiconductor substrate 100 may be oxidized, and a native oxide film 120 may thus be formed. Accordingly, the native oxide film 120 on the exposed semiconductor substrate 100 is etched and removed under fourth etching process conditions, as shown in FIG. 3E. For the fourth etching process conditions, the reaction gas(es) may include a fluorocarbon gas, as described above. Exemplary fourth etching process conditions include CF₄ at a flow rate of 40 to 60 sccm.

Accordingly, a hard mask pattern 130 may be formed, which comprises the pad oxide film pattern 102A, the polishing stop film pattern 104A, and the mask oxide film pattern 106A.

The pad oxide film pattern 102A is not necessarily provided. In this case, the hard mask pattern 130 comprises the polishing stop film pattern 104A and the mask oxide film pattern 106A.

Subsequently, as shown in FIG. 3F, the semiconductor substrate 100 is dry-etched under third etching process conditions using the hard mask pattern 130 to form a trench 200 for device-isolation film. In the third etching process conditions, the reaction gases may include an oxygen source as described above, a hydrogen halide source (e.g., a compound of the formula HX, HBX₄ or HPX₆, where X is F, Cl, Br, or I) and a halogen source (e.g., a compound of the formula X₂, where X is F, Cl, Br, or I). In accordance with the third etching process conditions, O₂, HBr and Cl₂ may be used as reaction gases. The mixing ratio of HBr and Cl₂ can be an essential factor to control the angle of formation of the trench 200 for a device-isolation film.

The third etching process conditions according to preferred embodiments of the present invention include O₂ at a flow rate of 2 to 5 sccm; HBr at a flow rate of 140 to 160 sccm; and Cl₂ at a flow rate of 15 to 25 sccm. In accordance with the third etching process conditions, a partial pressure ratio of O₂, HBr and Cl₂ may be 1:45˜55:6˜8.

In brief, exemplary third and fourth etching process conditions are summarized in Table 2 below:

TABLE 2

| | Fourth etching | Third etching |
|---|---|---|
| Items | process conditions | process conditions |
| O₂ (sccm) | 0 | 2~5 |
| HBr (sccm) | 0 | 140~160 |
| Cl₂ (sccm) | 0 | 15~25 |
| CF₄ (sccm) | 40~60 | 0 |

A level of the semiconductor substrate 100 exposed after the formation of the hard mask pattern 130 (e.g., removal of the native oxide 120) is controlled or monitored by end point detection (EPD).

Subsequently, an insulating material (not shown) is filled in the trench 200 for device-isolation film and is then subjected to chemical mechanical polishing (CMP). This process is well-known in the art and a detailed explanation thereof is thus omitted. The polishing stop film 104 serves as a polishing stop for the CMP step.

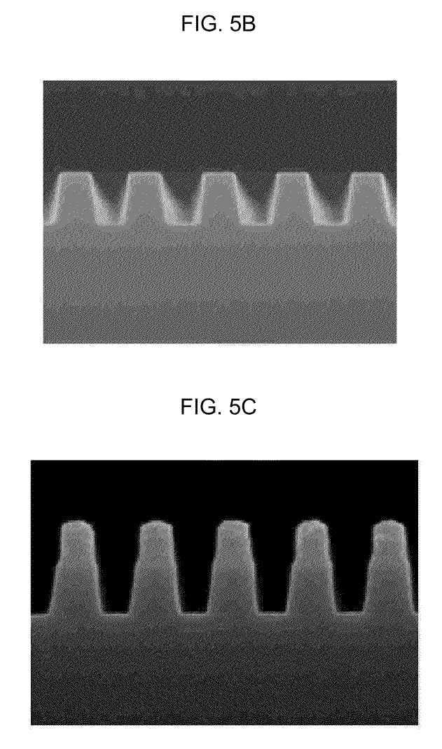

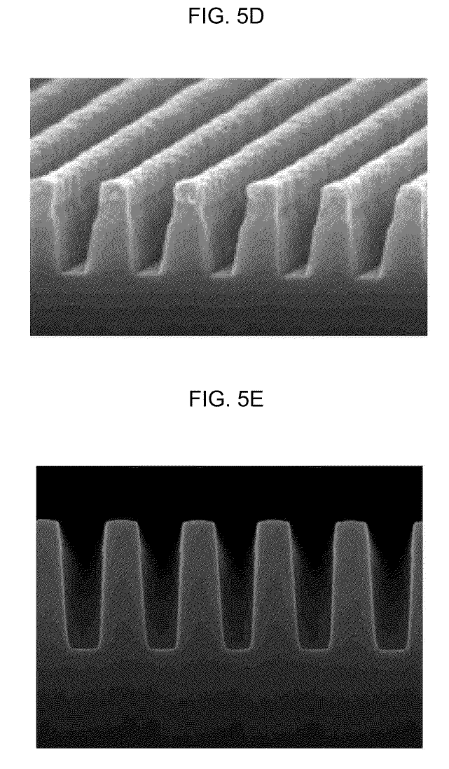

FIGS. 5A to 5E are SEM images of a semiconductor device manufactured by a method according to an exemplary embodiment of the present invention.

For example, for the first and second etching process conditions, when a ratio between CF₄ and CHF₃ is 45˜75:15˜25, edge profiles after etching show an undamaged hard mask and considerably low line edge roughness (LER), as shown in FIGS. 5A and 5B. FIG. 5B is a sectional-view taken along the line A-A′ in FIG. 5A. The photosensitive film pattern 110 left after etching the polishing stop film 104 and the mask oxide film 106 is shown in FIGS. 5C and 5D. FIG. 5D is an image scanned by slightly slanting the image of FIG. 5C.

In conclusion, as shown in FIG. 5E, the final profile of the trench for a device-isolation film is perfectly straight without any bent portions.

As is apparent from the foregoing, a method for manufacturing a semiconductor device forms a trench for a device-isolation film without using any spacer, thus advantageously simplifying an overall process, and securing a desired margin in the subsequent processes, namely, gap-filling an insulating material in the trench and chemical mechanical polishing of the insulating material.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a semiconductor device, comprising:
sequentially depositing a polishing stop film and a mask oxide film on a semiconductor substrate;
forming a photosensitive film pattern on the mask oxide film to expose a device isolation region;
sequentially etching the mask oxide film and the polishing stop film under the first and second etching process conditions using the photosensitive film pattern as a mask to form a hard mask pattern; and
etching the semiconductor substrate under third etching process conditions using the hard mask pattern to form a trench for a device-isolation film.

2. The method according to claim 1, further comprising:
etching and removing a native oxide film on the semiconductor substrate that is exposed after forming the hard mask pattern, wherein etching and removing the native oxide film is performed under fourth etching process conditions.

3. The method according to claim 1, wherein an etch selectivity ratio between the photosensitive film pattern and the mask oxide film is controlled by at least one amount or flow of a reaction gas and an RF power in the first etching process conditions.

4. The method according to claim 1, wherein a degree of straightness of etching the mask oxide film and the polishing stop film is controlled by a vacuum level of a chamber in which the mask oxide film and the polishing stop film are etched.

5. The method according to claim 1, wherein an exposed level of the semiconductor substrate after forming the hard mask pattern is controlled by end point detection.

6. The method according to claim 1, further comprising:
forming an anti-reflective film on the mask oxide film,
wherein the photosensitive film pattern is formed on the anti-reflective film.

7. The method according to claim 1, further comprising:
forming a pad oxide film on the semiconductor substrate,
wherein the polishing stop film is formed on the pad oxide film.

8. The method according to claim 1, wherein the polishing stop film comprises a silicon nitride film and the mask oxide film comprises a silicon oxide film.

9. The method according to claim 1, wherein the first etching process conditions include using CF₄ and CHF₃ as etching gases.

10. The method according to claim 9, wherein the first etching process conditions further include using O₂ as a reaction gas.

11. The method according to claim 10, wherein the first etching process conditions further include using Ar as an inert gas.

12. The method according to claim 11, wherein the first etching process conditions include:
O₂ at a flow rate of 5 to 10 sccm; Ar at a flow rate of 100 to 200 sccm; CF₄ at a flow rate of 30 to 50 sccm; and CHF₃ at a flow rate of 15 to 25 sccm.

13. The method according to claim 11, wherein a partial pressure ratio of O₂, Ar and CF₄ is 1:28˜36:14˜18.

14. The method according to claim 1, wherein the second etching process conditions include:
O₂ at a flow rate of 3 to 7 sccm; Ar at a flow rate of 100 to 200 sccm; and CF₄ at a flow rate of 70 to 90 sccm.

15. The method according to claim 1, wherein the third etching process conditions comprise using O₂, HBr and Cl₂ as reaction gases.

16. The method according to claim 15, wherein the third etching process conditions further include:
O₂ at a flow rate of 2 to 5 sccm; HBr at a flow rate of 140 to 160 sccm; and Cl₂ at a flow rate of 15 to 25 sccm.

17. The method according to claim 15, wherein a partial pressure ratio of O₂, HBr and Cl₂ is 1:45˜55:6˜8.

18. The method according to claim 2, wherein the fourth etching process conditions include:
CF₄ at a flow rate of 40 to 60 sccm.

19. The method according to claim 6, wherein the anti-reflective film has a thickness of 250˜350 Å.

20. The method according to claim 1, wherein the photosensitive film pattern has a thickness of 3,200˜3,600 Å.
